(19) United States
(12) Patent Application Publication
(10) Pub. No.: US 2014/0061721 A1
(43) Pub. Date: Mar. 6, 2014

(54) MOS DEVICE AND METHOD FOR FABRICATING THE SAME

(71) Applicants: Ching-Lin Chan, Yunlin County (TW); Shyi-Yuan Wu, Hsinchu City (TW); Cheng-Chi Lin, Yilan County (TW); Shih-Chin Lien, Taipei County (TW)

(72) Inventors: Ching-Lin Chan, Yunlin County (TW); Shyi-Yuan Wu, Hsinchu City (TW); Cheng-Chi Lin, Yilan County (TW); Shih-Chin Lien, Taipei County (TW)

(73) Assignee: MACRONIX INTERNATIONAL CO., LTD., Hsin-chu (TW)

(21) Appl. No.: 13/596,745

(22) Filed: Aug. 28, 2012

(51) Int. Cl. H01L 29/78; H01L 29/739; H01L 21/331; H01L 21/336

(52) U.S. Cl. 257/141; 257/343; 438/286; 438/135; 257/E29.256; 257/E21.409; 257/E29.197; 257/E21.382

(57) ABSTRACT

An improved MOS device is provided whereby the p-top layer is defined by a series of discretely placed p type top diffusion regions. The invention also provides methods for fabricating the MOS device of the invention.

### TECHNOLOGICAL FIELD

Embodiments of the present invention relate generally to a semiconductor device, in particular, a metal oxide semiconductor device, and a method for fabricating such a device.

### BACKGROUND

Diffused metal oxide semiconductor (DMOS) devices are characterized by a source region and a backgate region that are diffused at the same time. The transistor channel is formed by the difference in the two diffusions and not a separation implantation, which results in a decreased channel length. The shorter channel allows for low power dissipation and high speed capability.

A lateral diffused metal oxide semiconductor (LDMOS) device has its source and drain at the surface of the wafer causing a lateral current. Two important parameters in the design of LDMOS devices are breakdown voltage and on-state resistance. It is preferred to have a high breakdown voltage and a low on-state resistance to provide a device having relatively lower power consumption when operated under high voltage. Additionally, a low on-state resistance provides a higher drain current when the device is saturated, which tends to improve the operating speed of the device.

FIG. 1 illustrates a plan view of a drift region of a conventional LDMOS device. The LDMOS device 1 of FIG. 1 having a LDMOS region 10 called out by the box as illustrated. The LDMOS device 1 is defined by a source side 20 and a drain side 30.

FIG. 2 illustrates a plan view of the LDMOS region 10 called out in FIG. 1. The LDMOS region 10 having a plurality of p-type diffusion layers or p-top regions 40 substantially continuously extending from the source side 20 to the drain side 30, the plurality of p-top regions 40 disposed in a high voltage n-type well (HVNW). Thus, the conventional LDMOS region 10 is defined by sections of n-type grade or n-grade region 50 disposed on the plurality of p-top regions 40 separated by n-grade region 50 not disposed over any p-top layer.

FIG. 3A is a cross-sectional view of FIG. 2 taken along the AA′ section line. This representation of a conventional LDMOS has a p-substrate 60 in which an HVNW 70 has been disposed. A first p-well 80 is formed in the p-substrate 60 while a second p-well 90 is formed in the HVNW 70, the first p-well 80 having a p+ doped region 100 and the second p-well 90 having another p+ doped region 110 adjacent to an n+ doped source region 120. An n+ doped drain region 130 has been formed in the HVNW 70. This section of the LDMOS region 10 is represented by an n-grade region 50 disposed on one of the plurality of p-top regions 40. An etched field oxide isolation region 140 substantially separates the doped regions 100, 110, 120, 130.

Any control gate structure 150 known in the art may be used LDMOS device. For example the control gate structure 150 may comprise a conductive layer disposed on a dielectric layer. The control gate structure 150 may additionally comprise dielectric sidewall spacers. An etched interlayer dielectric (ILD) layer 160 is disposed over the defined structure. A first etched metal layer 170 is provided having a network of contacts through the ILD layer 160. The exemplary conventional LDMOS of FIG. 2 additionally shows an inter-metal dielectric (IMD) layer 180 upon which is disposed a second etched metal layer 190 providing a network of contacts through the IMD layer 180.

FIG. 3B is a cross-sectional view of FIG. 2 taken along the BB′ section line. This cross-sectional view of the conventional LDMOS has the same structure identified in FIG. 3A except that a p-top layer is not disposed in the HVNW 70.

High voltage LDMOS devices have a variety of uses in semiconductors. For example, LDMOS devices may be used to convert relatively high voltage to relatively low voltage or as switching power transistors that are configured to drive a load. However, the specific on-resistance of the conventional high voltage LDMOS can still be too high as a result of the interaction between the n-grade region and the fully doped p-type region. There remains a need in the art for improved LDMOS devices, in particular, high voltage LDMOS devices having an even lower specific on-resistance.

### BRIEF SUMMARY OF EXEMPLARY EMBODIMENTS

Embodiments of the present invention provide semiconductor devices, in particular, metal oxide semiconductor devices.

An aspect of the invention comprises a MOS device comprising a p-substrate; a high voltage n-well (HVNW) disposed in the p-substrate; a first p-well formed in the p-substrate having a first p+ doped region; a second p-well formed in the HVNW having a second p+ doped region adjacent to an n+ doped source region; a discrete p-top region having a plurality of p-top segments disposed in the HVNW; and an n-grade region disposed above the discrete p-top region. The plurality of p-top segments have a distance from the n-grade region to define a plurality of distances, a width to define a plurality of widths and a separation distance with an adjacent p-top segment to define a plurality of separation distances. In certain embodiments of the invention, the plurality of distances may be the same, while in certain other embodiments of the invention, the plurality of distances are increasing.

In an embodiment of the invention, the MOS device is a LDMOS device and the HVNW has an n+ doped drain region.

In certain embodiments of the invention, the number of p-top segments, each of the distances between each of the p-top segments and the n-grade region, the widths of each of the p-top segments, and the separation distances between the p-top segments are such that there is at least about a 15% reduction in on-resistance at a drain voltage of about 1 volt in comparison to another LDMOS device having by a continuous p-top region. In certain embodiments of the invention, a breakdown voltage of the LDMOS device is about the same as a breakdown voltage of the LDMOS device having a continuous p-top region.

The MOS device may additionally comprise a field oxide isolation region to isolate the first p+ doped region from the second p+ doped region that is adjacent to the n+ doped source region and the doped region of the HVNW. For example, the field oxide isolation region LDMOS device isolates the first p+ doped region from the second p+ doped region that is adjacent to the n+ doped source region and the n+ doped drain region of the HVNW.

The MOS structure may additionally comprise a gate structure disposed between the n+ doped source region and the dope region of the HVNW. For example, the LDMOS device comprises a gate structure disposed between the n+ doped source region and the n+ dope drain region of the HVNW.

In certain embodiments of the invention, the MOS device may be an insulated gate bipolar transistor wherein a third p+ doped region is disposed in the HVNW. In certain embodiments of the invention, the MOS device may be a diode wherein an n+ doped drain region is disposed in the HVNW.

An aspect of the invention also provides a method for fabricating a MOS device comprising the steps of providing a p-substrate, forming a high voltage n-well (HVNW) into the p-substrate, forming a first p-well in the p-substrate, forming a second p-well in the HVNW, forming a discrete p-top region in the HVNW, the discrete p-top region having a plurality of p-top segments, and disposing an n-grade region in the HVNW above the discrete p-top region. The plurality of p-top segments have a distance from the n-grade region to define a plurality of distances, a width to define a plurality of widths and a separation distance with an adjacent p-top segment to define a plurality of separation distances. In certain embodiments of the invention, the plurality of distances may be the same, while in certain other embodiments of the invention, the plurality of distances are increasing.

The method of fabricating a MOS device may additionally comprise forming a field oxide isolation region. The field oxide isolation having a first field structure overlapping the first p-well and the second p-well and a second field oxide structure overlapping the n-grade region.

The method fabricating a MOS device may additionally comprise forming a gate structure. For example, a gate structure may be formed by performing a gate oxidation, forming a polysilicon layer, and forming a spacer surrounding the gate structure.

The method of fabricating a MOS device may additionally comprise the steps of forming an n+ doped source region in the second p-well adjacent to the gate structure, forming a first p+ doped region in the first p-well, forming a second p+ doped region in the second p-well, and forming a doped region adjacent to the second field oxide structure in the HVNW.

In certain embodiments of the invention, the doped region may be an n+ doped drain region and the MOS device may be either a LDMOS device or a diode. In certain other embodiments of the invention, the doped region may be another p+ doped region and the MOS device may be an insulated gate bipolar transistor.

In the case of the LDMOS device, the number of p-top segments, the widths of the p-top segments, the distances of each of the p-top segments from the n-grade region, and the separation distances between the p-top segments are such that there is at least about a 15% reduction at a drain voltage of about 1 volt in comparison to another LDMOS device having a continuous p-top region.

Another aspect of the invention further comprises a product fabricated from the methods of the invention.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates a plan view of an LDMOS device;

FIG. 2 illustrates a plan view of an LDMOS region;

FIG. 3A illustrates a cross sectional view of the LDMOS region shown in FIG. 2 taken along section lines AA′;

FIG. 3B illustrates a cross sectional view of the LDMOS region shown in FIG. 2 taken along section lines BB′;

FIG. 4 illustrates a plan view of an LDMOS region according to an embodiment of the invention;

FIG. 5A illustrates a cross sectional view of an LDMOS region shown in FIG. 4 taken along section lines AA′ according to an embodiment of the invention;

FIG. 5B illustrates a cross sectional view of an LDMOS region shown in FIG. 4 taken along section lines BB′ according to an embodiment of the invention;

FIGS. 6A and 6B are cross-sectional views of FIG. 4 taken along the AA′ and BB′ section lines respectively after the high voltage n-well has been formed into the p-substrate according to an embodiment of the invention;

FIGS. 7A and 7B are cross-sectional views of FIG. 4 taken along the AA′ and BB′ section lines respectively after the first p-well is formed in the p-substrate and a second p-well is formed in the HVNW according to an embodiment of the invention;

FIGS. 8A and 8B are cross-sectional views of FIG. 4 taken along the AA′ and BB′ section lines respectively after forming the discrete p-top region in the HVNW according to an embodiment of the invention;

FIGS. 9A and 9B are cross-sectional views of FIG. 4 taken along the AA′ and BB′ section lines respectively after disposing the n-grade region within the HVNW according to an embodiment of the invention;

FIGS. 10A and 10B are cross-sectional views of FIG. 4 taken along the AA′ and BB′ section lines respectively after forming the field oxide isolation region according to an embodiment of the invention;

FIGS. 11A and 11B are cross-sectional views of FIG. 4 taken along the AA′ and BB′ section lines respectively after performing a gate oxidation process according to an embodiment of the invention;

FIGS. 12A and 12B are cross-sectional views of FIG. 4 taken along the AA′ and BB′ section lines respectively after forming a polysilicon layer of the control gate structure according to an embodiment of the invention;

FIGS. 13A and 13B are cross-sectional views of FIG. 4 taken along the AA′ and BB′ section lines respectively after forming a spacer surrounding the control gate structure according to an embodiment of the invention;

FIGS. 14A and 14B are cross-sectional views of FIG. 4 taken along the AA′ and BB′ section lines respectively after an n+ doped source region is formed in the second p-well and an n+ doped drain region is formed in the HVNW according to an embodiment of the invention;

FIGS. 15A and 15B are cross-sectional views of FIG. 4 taken along the AA′ and BB′ section lines respectively after a p+ doped region is formed in the first p-well and another p+ doped region is formed in the second p-well according to an embodiment of the invention;

FIGS. 16A and 16B are cross-sectional views of FIG. 4 taken along the AA′ and BB′ section lines respectively after applying an interlayer dielectric layer according to an embodiment of the invention;

FIGS. 17A and 17B are cross-sectional views of FIG. 4 taken along the AA′ and BB′ section lines respectively after applying a first metal layer according to an embodiment of the invention;

FIGS. 18A and 18B are graphical representations of a TCAD simulation showing the impact generation rate at breakdown for a conventional LDMOS device;

FIGS. 19A and 19B are graphical representations of a TCAD simulation showing the impact generation rate at breakdown for a LDMOS device according to an embodiment of the invention;

FIGS. 20A and 20B are graphical representations of a TCAD simulation showing the potential profile at breakdown for a conventional LDMOS device;

FIGS. 21A and 21B are graphical representations of a TCAD simulation showing the potential profile at breakdown for a LDMOS device according to an embodiment of the invention;

FIG. 22A is a graphical representation of the drain voltage versus the drain current for a conventional LDMOS device and an exemplary LDMOS device according to an embodiment of the invention;

FIG. 22B is another graphical representation of the drain voltage versus the drain current for a conventional LDMOS device and an exemplary LDMOS device according to an embodiment of the invention;

FIG. 23 illustrates a plan view of a LDMOS device according to an embodiment of the invention;

FIG. 24 illustrates a detail plan view of a portion of the LDMOS device of FIG. 23 showing four discrete p-top segments according to an embodiment of the invention;

FIG. 25 illustrates a detail plan view of a portion of the LDMOS device of FIG. 23 showing four discrete p-top segments according to an embodiment of the invention;

FIG. 26A illustrates a cross-sectional view of the LDMOS device fully illustrated in FIG. 5A according to an embodiment of the invention;

FIG. 26B illustrates a more detailed cross-sectional view of the LDMOS device illustrated in FIG. 26A according to an embodiment of the invention;

FIG. 27A illustrates a cross-sectional view of an N-channel metal oxide semiconductor device having a discrete p-top region according to an embodiment of the invention;

FIG. 27B illustrates a cross-sectional view of an n-grade section of the N-channel metal oxide semiconductor device without the discrete p-top region according to an embodiment of the invention;

FIG. 28A illustrates a cross-sectional view of an insulated gate bipolar transistor device having a discrete p-top region according to an embodiment of the invention;

FIG. 28B illustrates a cross-sectional view of an n-grade section of the insulated gate bipolar transistor device without the discrete p-top region according to an embodiment of the invention;

FIG. 29A illustrates a cross-sectional view of a diode having a discrete p-top region according to an embodiment of the invention;

FIG. 29B illustrates a cross-sectional view of an n-grade section of the diode without the discrete p-top region; and

FIG. 30 is a flowchart illustrating a process for fabricating a LDMOS device according to an embodiment of the invention.

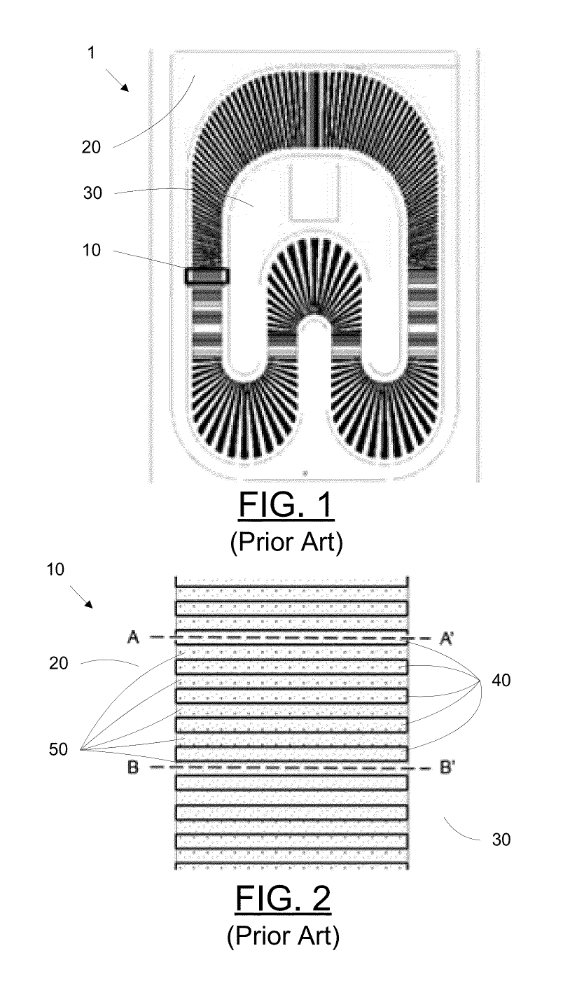

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a gate structure” includes a plurality of such gate structures.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “MOS device” refers to a metal oxide semiconductor device. Lateral diffused metal oxide semiconductor (LDMOS), N-channel metal oxide semiconductor (NMOS), insulated gate bipolar transistor (IGBT), and diodes are each examples of a MOS device. Such devices may be designed to accommodate high voltages or even ultra-high voltages relatively to other semiconductor devices.

As used herein, “LDMOS device” refers to a metal oxide field effect transistor (MOSFET) having coplanar source and drain regions. According to certain embodiments, the LDMOS device of the invention is characterized by a high breakdown voltage and a low on-state resistance. I.e., the LDMOS device of the invention and methods of manufacturing such devices results in a LDMOS device having a relatively high breakdown voltage. Additionally, the LDMOS device of the invention and methods of manufacturing such devices results in a LDMOS device having a relatively low on-state resistance in comparison to other LDMOS devices known in the art.

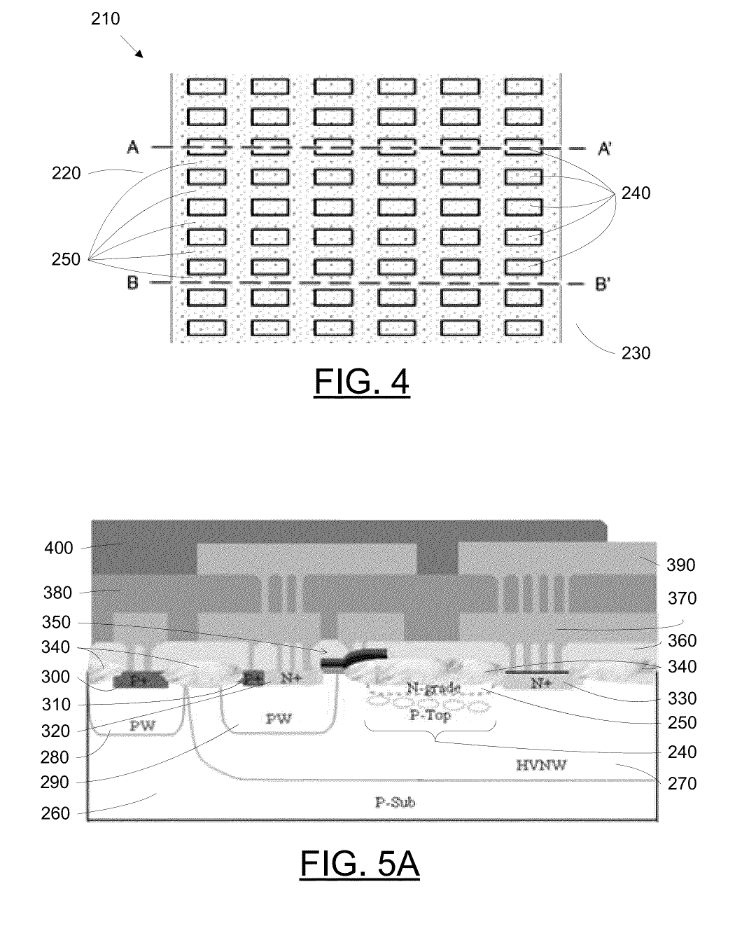

FIG. 4 illustrates a plan view of the LDMOS region 210 according to an exemplary embodiment of the invention. The LDMOS region 210 having a plurality of discretely placed p-type diffusion layers or p-top layer, each p-top layer having a series of discretely placed p-type top regions or discrete p-top regions 240 extending from the source side 220 to the drain side 230, the discrete p-top regions 240 disposed in a high voltage n-type well (HVNW). Thus, the LDMOS region 210, according to an embodiment of the invention, is defined by sections of n-type grade or n-grade region 250 disposed on the plurality of discrete p-top regions 240 separated by n-grade region 250 not disposed over any p-top layer.

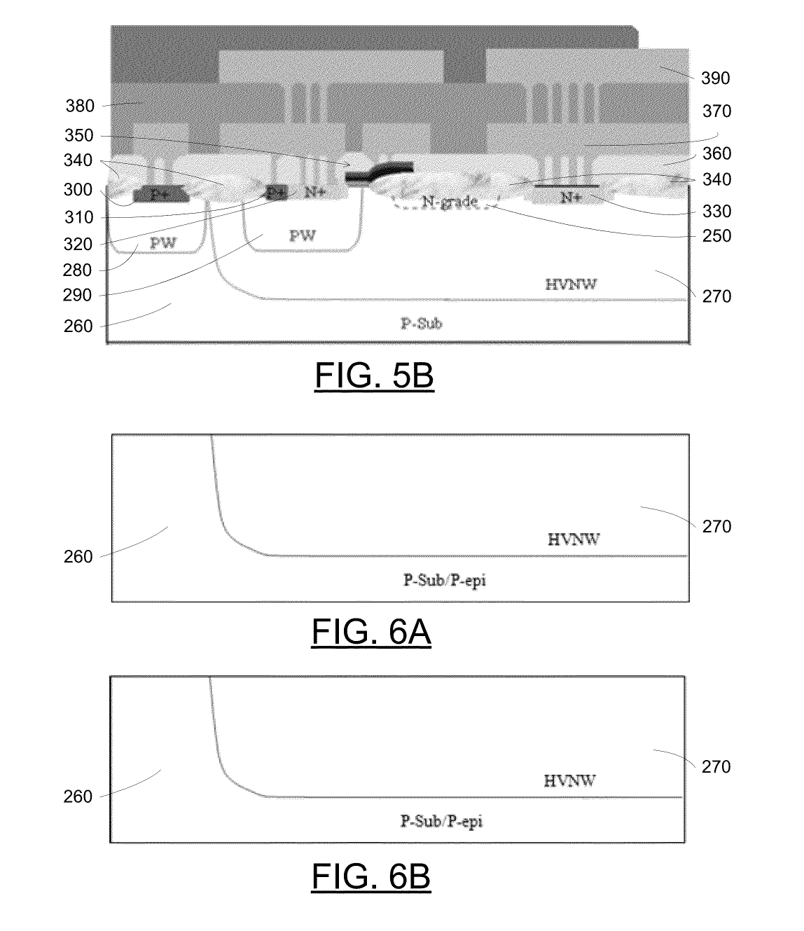

FIG. 5A is a cross-sectional view of FIG. 4 taken along the AA′ section line according to an embodiment of the invention. This exemplary representation of a LDMOS device, according to an embodiment of the invention, has p-type semiconductor substrate or a p-substrate 260, which may be formed in whole or in part as a p-type epitaxial layer, in which an HVNW 270 has been disposed. A first p-well 280 is formed in the p-substrate 260 while a second p-well 290 is formed in the HVNW 270, the first p-well 280 having a p+ doped region 300 and the second p-well 290 having another p+ doped region 310 adjacent to an n+ doped source region 320. An n+ doped drain region 330 has been formed in the HVNW 270. This section of the LDMOS region 210 is represented by an n-grade region 250 disposed on one of the plurality of discrete p-top regions 240. A field oxide isolation region 340 substantially separates the doped regions 300, 310 & 320, 330.

Any control gate structure 350 known in the art may be used LDMOS device. For example the control gate structure 350 may comprise a conductive layer disposed on a dielectric layer. The control gate structure 350 may additionally comprise dielectric sidewall spacers. An interlayer dielectric (ILD) layer 360 is disposed over the defined structure. A first metal layer 370 is provided having a network of contacts through the ILD layer 360. The exemplary embodiment of a LDMOS device of FIG. 4 additionally shows an inter-metal dielectric (IMD) layer 380 upon which is disposed a second etched metal layer 390 providing a network of contacts through the IMD layer 380.

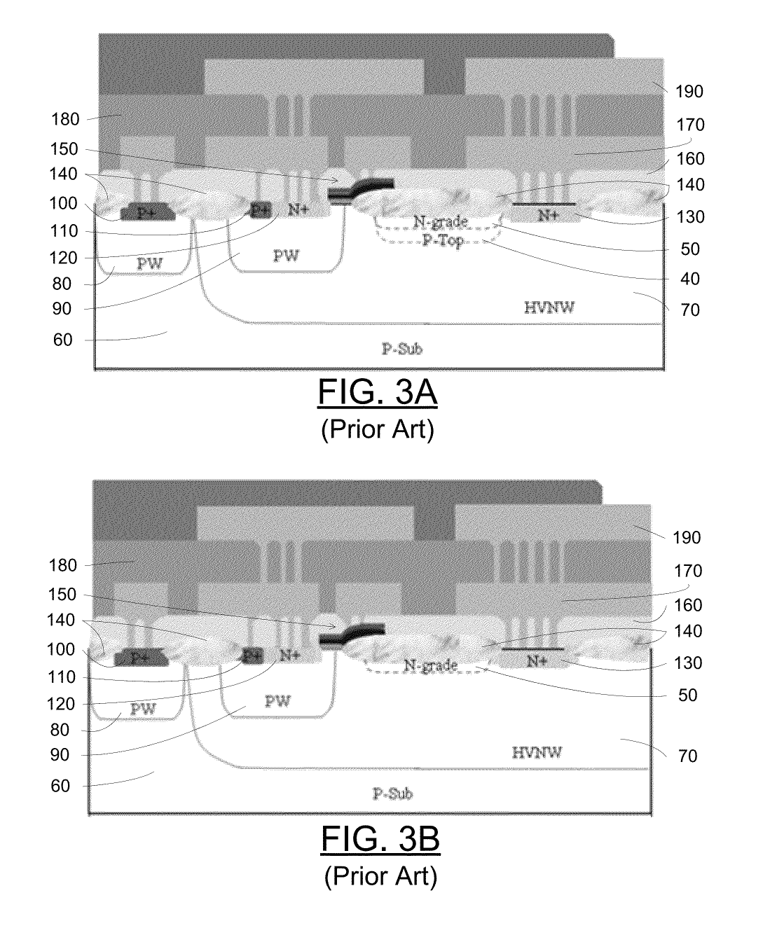

FIG. 5B is a cross-sectional view of FIG. 4 taken along the BB′ section line. This cross-sectional view of the LDMOS device, according to an embodiment of the invention, has the same structure identified in FIG. 5A except that a discrete p-top layer is not disposed in the HVNW 270. Thus, according to this exemplary embodiment of the invention, the cross section of the conventional structure as shown in FIG. 3B and the cross section of the LDMOS device of the invention as shown in FIG. 5B may be substantially similar. Of course, the cross section of the conventional structure as shown in FIG. 3A and the cross section of the LDMOS device of the invention as shown in FIG. 5A being different.

FIGS. 6A-17B are cross-sectional views of the LDMOS device after the completion of a described step in fabricating the LDMOS device of the invention. Each of the figures ending with an “A” are illustrative of the cross-section of the LDMOS device taken along the AA′ section line of FIG. 4—i.e., showing the p-top region 240—while each of the figures ending with a “B” are illustrative of the cross-section of the LDMOS device taken along the BB′ section line of FIG. 4—i.e., showing only the n-grade region 250.

FIGS. 6A and 6B are cross-sectional views of FIG. 4 taken along the AA′ and BB′ section lines respectively after the high voltage n-well (HVNW) 270 has been formed into the p-substrate 260. The HVNW 270 extends downwardly beginning at an upper portion of the p-substrate 260. The process of forming the HVNW 270 typically may involve depositing a photoresist to define the region where the HVNW 270 will be formed into the p-substrate 260 followed by patterning and developing the desired pattern and location of the HVNW 270. An implantation may then be performed through the patterned and developed photomask and into, for example, an epitaxial layer of the p-substrate 260. In certain embodiments of the invention, the implantation is followed by an n-well drive-in step. The drive-in step typically occurs at an elevated temperature for some period of time. In certain embodiments of the invention, the elevated temperature of the drive-in step is anywhere in a range of from about 1,000° C. to about 1,150° C. for a period of time anywhere in a range of from about 20 minutes to about 2 hours. In certain embodiments of the invention, the drive-in process has a temperature of about 1,150° C. for about 1 hour. Any remaining photoresist typically may be commensurately removed with processing of the HVNW 270 or subsequently removed after processing of the HVNW 270 is complete.

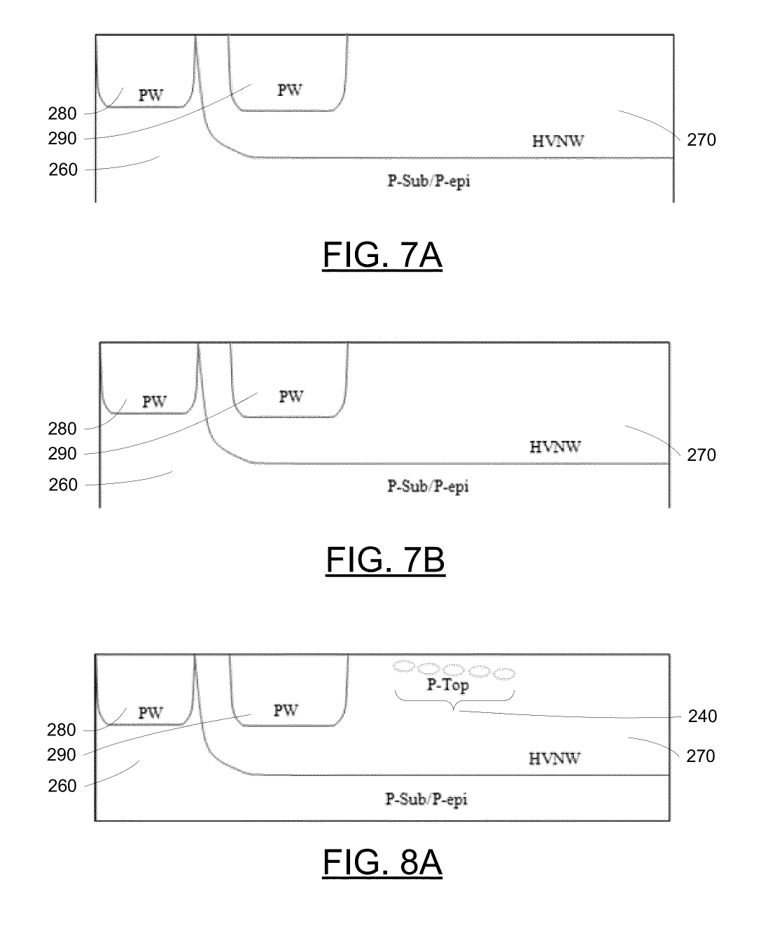

FIGS. 7A and 7B are cross-sectional views of FIG. 4 taken along the AA′ and BB′ section lines respectively after the first p-well 280 is formed in the p-substrate 260 and a second p-well 290 is formed in the HVNW 270. A p-type well is formed by use of a photolithographic technique and introduction of a p-type impurity ion implantation into the desired layer. In certain embodiments of the invention, the ion implantation step may be followed by a p-well drive-in step, whereby the conditions of the drive-in step as previously described herein. The process may also encompass the removal of any remaining photoresist. The first p-well 280 and the second p-well 290 may be substantially simultaneously formed or may be formed by using separate steps, with the latter technique being preferred if separate types of ions are to be implanted in the p-substrate 260 and the HVNW 270, respectively.

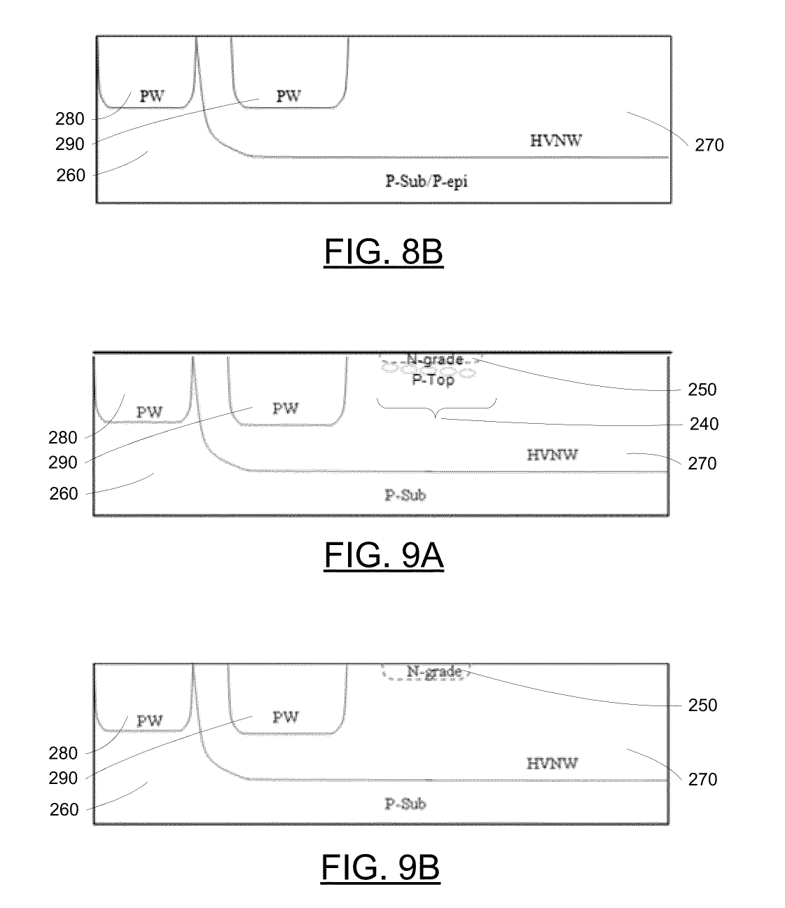

FIGS. 8A and 8B are cross-sectional views of FIG. 4 taken along the AA′ and BB′ section lines respectively after forming the discrete p-top region 240 in the HVNW 270. The discrete p-top region 240 is a p-type top diffusion region having more than one discretely formed p-top segments to define the overall discrete p-top region 240. In certain embodiments of the invention, the discrete p-top region 240, comprise two, three, four, five, six, seven, eight, nine, or ten or more discrete p-top segments.

Without intending to be bound by theory, the discrete p-top region 240 is configured to improve charge balancing and to reduce the specific on-resistance of the LDMOS device. Without further intending to be bound by theory, the discrete p-top region 240 is configured to allow for downward depletion into the extended drain region of the HVNW 270 in combination with upward depletion from the p-substrate 260 to not be materially affected providing a substantially similar breakdown voltage to conventional LDMOS devices. Doping of the HVNW 270 will then be such that a lower specific on-resistance may be achieved.

In certain embodiments of the invention, the discrete p-top region is disposed proximate to the second p-well 290. For example, the number of discrete p-top segments, the positioning of each of the p-top segments within the HVNW 270, the positioning of each of the p-top segments relative to each other, as well as other parameters, as further described herein, will affect the extent of reduction in specific on-resistance of the LDMOS device.

A p-top segment of the discrete p-top region 240 may be formed by depositing a photoresist to define the region where the p-top segment will be formed into the HVNW 270 followed by patterning and developing the desired pattern and location of the p-top segment. An implantation of p-type ions may then be performed through the patterned and developed photomask depositing the p-top segment into the HVNW 270. According to certain embodiments of the invention, a p-type ion may be selected, for example, from any one or more elements from a Group IIIA element of the Periodic Table with boron, for example, being commonly selected according to certain embodiments of the invention. In certain embodiments of the invention, the desired p-type ions may be formed from compounds having at least one element from Group IIIA with at least one element from Group IVA. For example, according to an embodiment of the invention, the p-type ion may have the general formula SiₓB_{y}.

Of course, the processing for implanting the p-top segment may be concluded by removing any excess photoresist from the device. Each of the p-top segments of the discrete p-top region 240 may be simultaneously formed or even formed over two or more photolithographic and implantation steps in forming the discrete p-top region 240. Two more steps may be particularly useful when forming a discrete p-top region 240 having, for example, variable depths within the HVNW 270 and/or variable concentrations of p-type ions among the p-top segments and/or even layering of part or all of a p-top segment over another p-top segment, with such segments capable of being joined and or separated within the discrete p-top region 240. Finally, as shown in FIG. 8B, a discrete p-top region is not disposed in this region of the LDMOS device.

FIGS. 9A and 9B are cross-sectional views of FIG. 4 taken along the AA′ and BB′ section lines respectively after disposing the n-grade region 250 within the HVNW 270. The n-grade region 250 is implanted in the HVNW 270 by depositing a photoresist to define the region where the n-grade region 250 will be formed into the HVNW 270 followed by patterning and developing the desired pattern identifying the location of the n-grade region 250. An implantation of n-type ions may then be performed through the patterned and developed photomask depositing the n-grade region 250 into the HVNW 270. According to certain embodiments of the invention, the n-type ion may be selected, for example, from any one or more elements from a Group VA element of the Periodic Table, for example, phosphorus according to certain embodiments of the invention. In certain embodiments of the invention, the desired n-type ions may be formed from compounds having at least one element from Group VA with at least one element from Group IVA, for example, having a general form of SiₓP_{y}.

According to certain embodiments of the invention, the n-grade region 250 is implanted directly above the region in the HVNW 270 where the discrete p-top region 240 is formed. In certain embodiments of the invention, the n-grade region 250 is implanted such that it substantially covers the discrete p-top region 240. In yet other embodiments of the invention, the n-grade region is implanted such that it just covers the discrete p-top region 250, which is similar to the exemplary embodiment of FIG. 9A. In other, less preferred embodiments of the invention, the n-grade region 250 does not entirely cover the discrete p-top region 240.

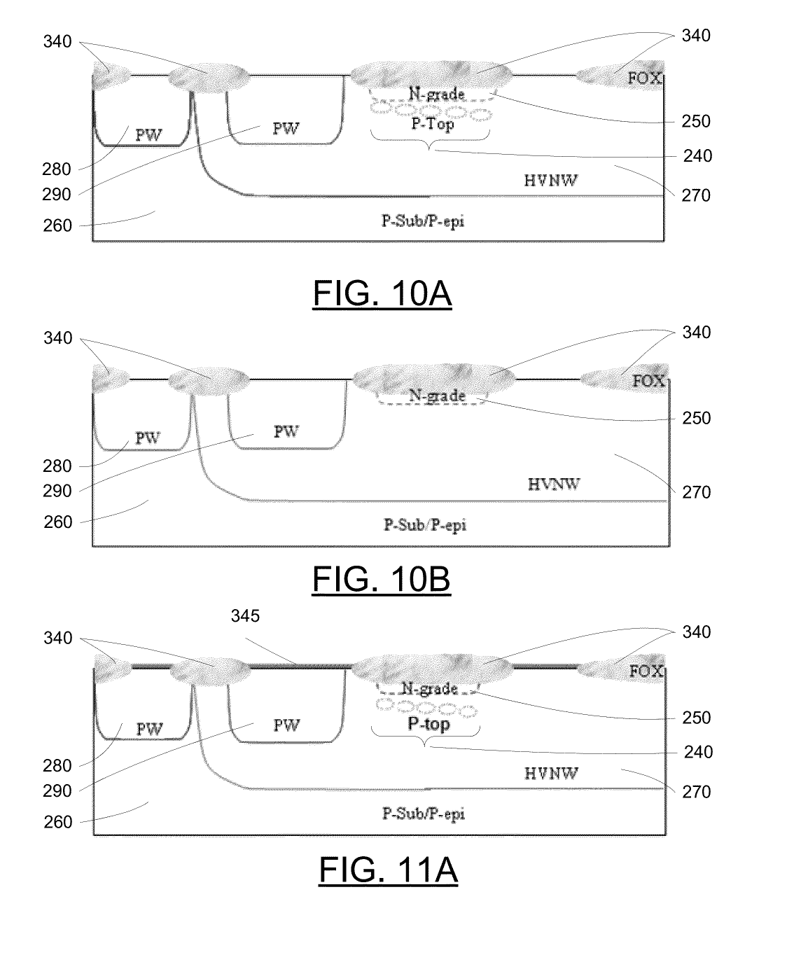

FIGS. 10A and 10B are cross-sectional views of FIG. 4 taken along the AA′ and BB′ section lines respectively after forming the field oxide isolation region 340. According to an embodiment of the invention, the field oxide isolation region 340 comprises a plurality of field oxide isolation structures separating various regions of the LDMOS device. For example, in the exemplary embodiment of FIGS. 10A and 10B, the field oxide isolation region 340 comprises filed oxide isolation structures separating various doped regions that will eventually be formed in the first p-well 280, the second p-well 290, and the HVNW 270.

According to an embodiment of the invention, the field oxide isolation region 340 may be formed by first applying a relatively thick layer of field oxide, for example, 1 micron or greater according to some embodiments of the invention, is grown along the top surface of the LDMOS device and then masked and etched to defined certain portions of the top surface, as represented in FIGS. 10A and 10B.

In certain other embodiments of the invention the field oxide isolation region 340 is grown about and then etched to isolate certain regions of the LDMOS device. For example, a substantially uniform field oxide layer may be applied using a field oxide diffusion. A photoresist may be applied to the grown field oxide layer and then patterned and developed to identify areas where certain portions of the field oxide isolation layer may be etched away. Following the etching process, any remaining photoresist may be removed and a plurality of field oxide structures remain to define the field oxide isolation region 340. In certain other embodiments of the invention, a precursor material such as a pad oxide and/or a silicon nitride may be similarly applied and a field oxide oxidation process creates the field oxide in the structures that are defined by etching.

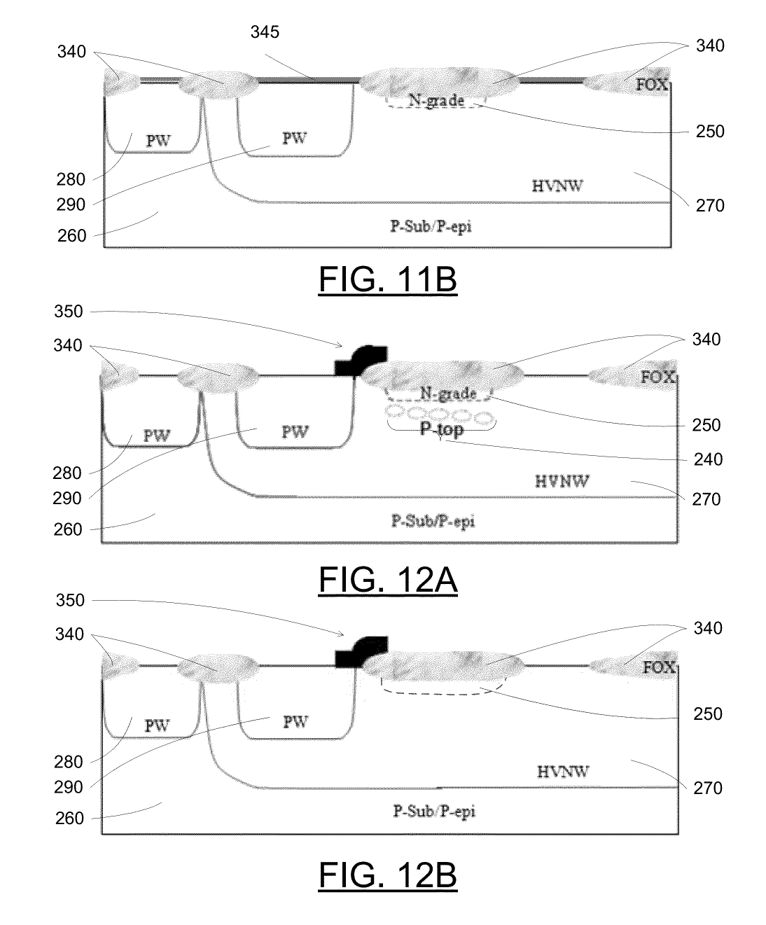

FIGS. 11A and 11B are cross-sectional views of FIG. 4 taken along the AA′ and BB′ section lines respectively after performing a gate oxidation process to form a gate oxide layer 345. The gate oxidation process comprises a sacrificial oxidation step whereby an oxide is grown into a silicon surface by exposing the silicon surface to oxygen under certain conditions over a period of time. Typically, the sacrificial oxidation process is carried out at an elevated temperature, for example, a temperature in a range of from about 800° C. to about 1,000° C. or even greater. In certain embodiments of the invention, the elevated temperature is within the range of from about 850° C. to about 950° C. In yet other embodiments of the invention, the elevated temperature is about 900° C.

The sacrificial oxidation process may be followed by a gate clean process or more appropriately a pre-gate clean process to remove native oxide from the surface where the control gate will be applied. Any pre-gate clean process known in the art may be used. For example, the pre-gate clean process may employ the use of HF, HCl or ozone to clean the desired area where a gate oxide is to be formed. Finally, a gate oxidation step is employed to form a gate oxide layer 345.

FIGS. 12A and 12B are cross-sectional views of FIG. 4 taken along the AA′ and BB′ section lines respectively after forming a polysilicon layer of the control gate structure 350. The process of forming the polysilicon layer comprises depositing, typically using a chemical vapor deposition process, a polysilicon on the gate oxide layer 345. The polysilicon deposition is followed by depositing a tungsten silicide (WSiₓ), which, in combination with the polysilicon layer, is known as the polycide. A photolithographic processing step will be used to define the region where the polycide layer will remain after etching. Upon completion of etching, the polysilicon layer defining the control gate structure 350 remains.

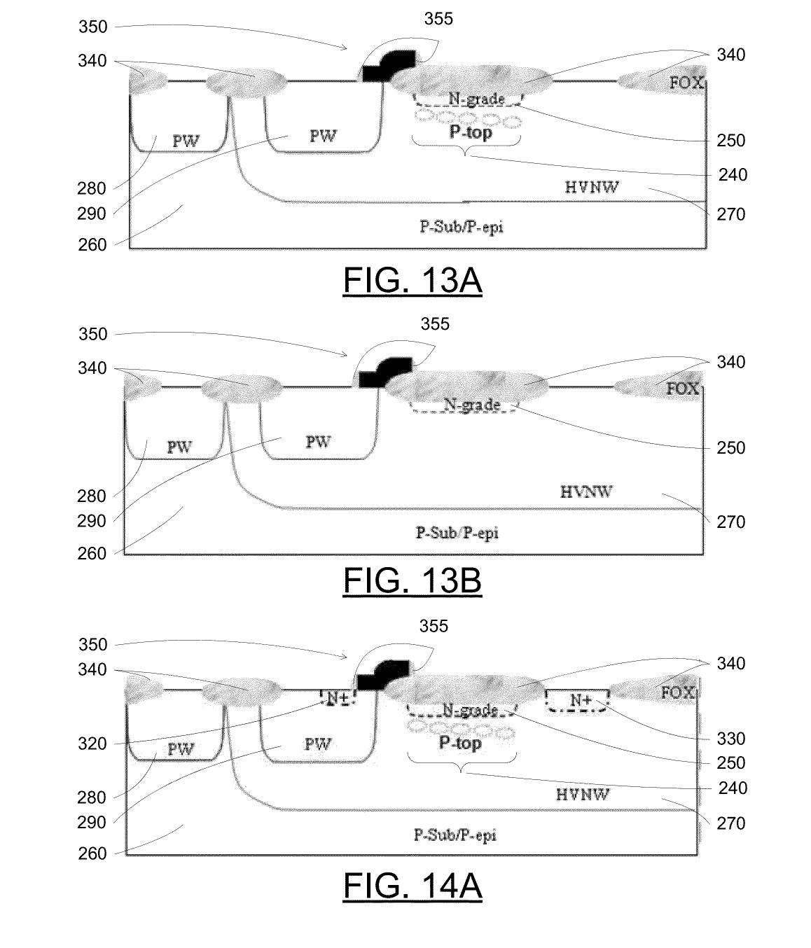

FIGS. 13A and 13B are cross-sectional views of FIG. 4 taken along the AA′ and BB′ section lines respectively after forming a spacer 355 surrounding the polysilicon layer of the control gate structure 350. In an embodiment of the invention a conformal layer of tetraethylorthosilane (TEOS) is deposited to the surface of the LDMOS device. Photolithography may be used to define the remaining spacer 355 surrounding the control gate structure 350. The masked surface is then etched to form the spacer 355 surrounding the control gate structure 350. (More aptly, the spacer 355 may also be considered a part of the control gate structure 350.)

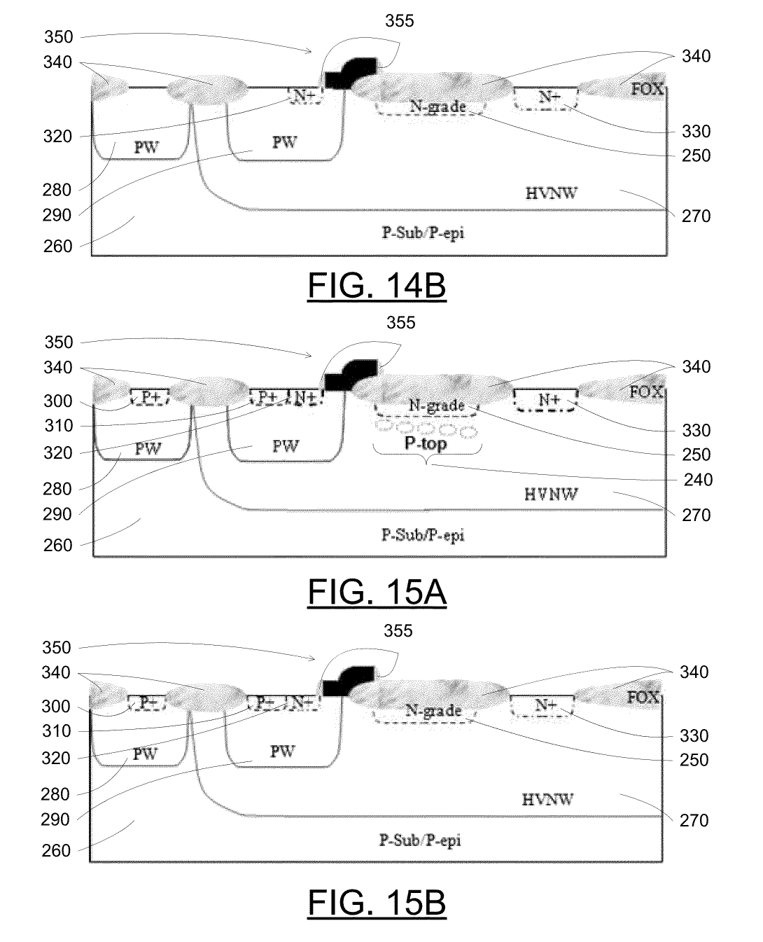

FIGS. 14A and 14B are cross-sectional views of FIG. 4 taken along the AA′ and BB′ section lines respectively after the n+ doped source region 320 is formed in the second p-well 290 and the n+ doped drain region 330 is formed in the HVNW 270. Each of the n+ doped regions 320, 330 may be implanted into their respective regions by depositing a photoresist to define where the n+ doped regions 320, 330 will be formed followed by patterning and developing the desired pattern identifying the location of the n+ doped regions 320, 330. N+ ions may then be implanted or injected into the regions defined by the photomask to form the n+ doped source region 320 into the second p-well 290 and the n+ doped drain region 330 into the HVNW 270. In certain embodiments of the invention, each of these n+ doped regions 320, 330 may be formed using separate procedures having steps similar to those define above.

FIGS. 15A and 15B are cross-sectional views of FIG. 4 taken along the AA′ and BB′ section lines respectively after the p+ doped region 300 is formed in the first p-well 280 and the p+ doped region 310 is formed in the second p-well 290. In certain embodiments of the invention, the p+ doped region 310 of the second p-well 290 is adjacent to the n+ doped source region 320 of the second p-well 290.

Each of the p+ regions 300, 310 may be implanted into their respective regions by depositing a photoresist to define where the p+ regions 300, 310 will be formed followed by patterning and developing the desired pattern identifying the location of the p+ regions 300, 310. P+ ions may then be implanted or injected into the regions defined by the photomask to form the p+ region 300 into the first p-well 280 and the p+ region 310 into the second p-well 290. In certain embodiments of the invention, each of these p+ regions 300, 310 may be formed using separate procedures having steps similar to those define above.

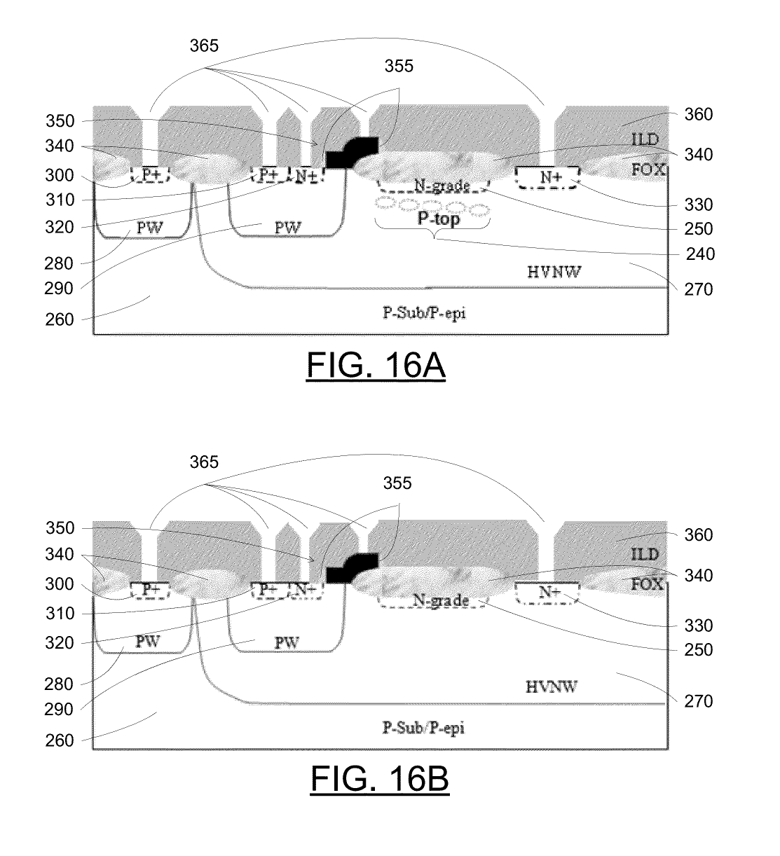

FIGS. 16A and 16B are cross-sectional views of FIG. 4 taken along the AA′ and BB′ section lines respectively after applying an interlayer dielectric (ILD) layer 360. The ILD layer 360 may be applied by first depositing an interlayer dielectric material to the LDMOS device. Photolithography may then be used to create a patterned photoresist to define the first core regions 365 where a conductive material will be applied. Finally the first core regions 365 will be etched to determine the structure of the ILD layer 360.

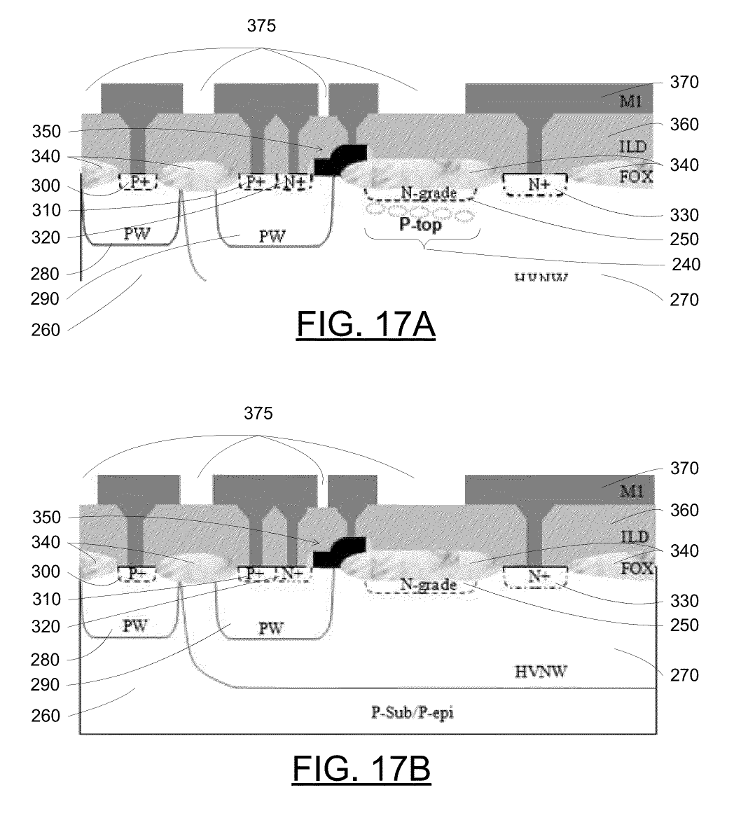

FIGS. 17A and 17B are cross-sectional views of FIG. 4 taken along the AA′ and BB′ section lines respectively after applying a first metal layer 370. A first metal of the first metal layer 370 is deposited along the ILD layer 360 substantially filling the first core regions 365 defined within the ILD layer 360. Photolithography may then be used to create a patterned photoresist to define the isolation regions 375 where a dielectric material of the inter-metal dielectric (IMD) layer 380 will be applied. Finally the isolation regions 375 will be etched to determine the structure of the first metal layer 370.

Subsequent layers may similarly be applied. For example, as shown in the exemplary illustrative embodiment represented in FIGS. 5A and 5B an IMD layer 380 may be applied to the first metal layer 370. A second metal layer 390 having second isolation regions may then be applied to the IMD layer 380. Another dielectric layer 400, for example, may be applied to the second metal layer 390.

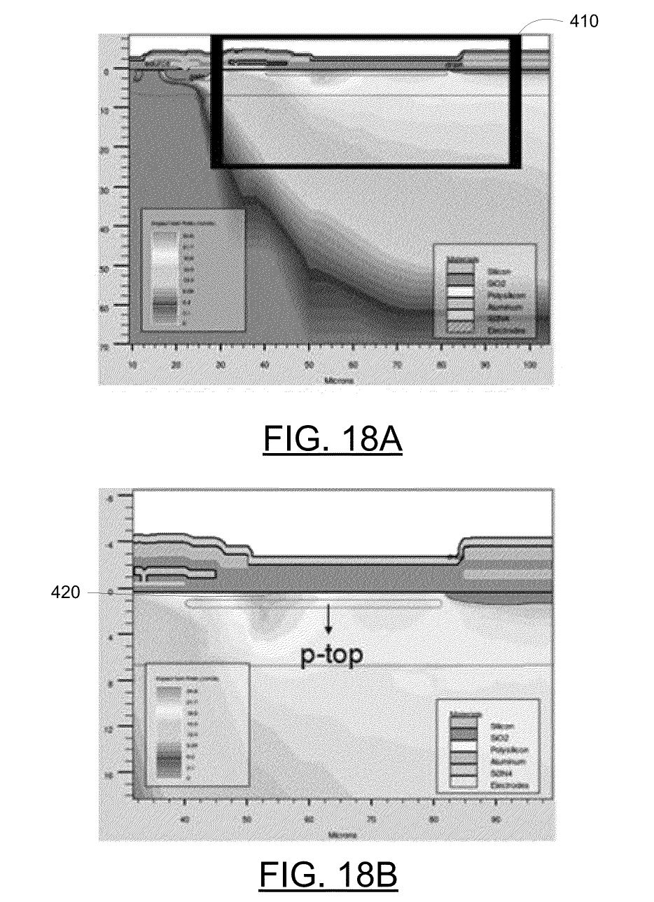

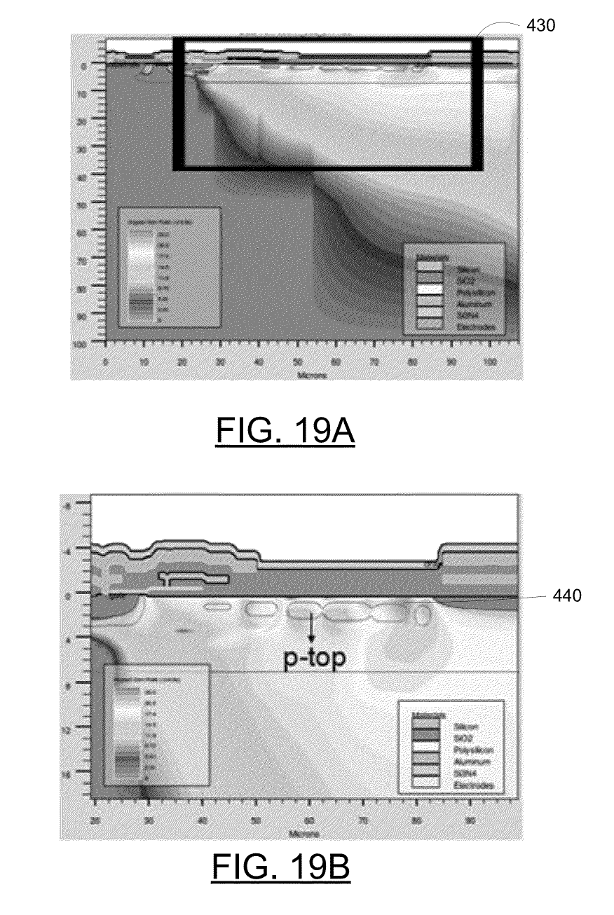

FIG. 18A is a graphical representation of a TCAD simulation showing the impact generation rate at breakdown for a conventional LDMOS device. FIG. 18B is a more detailed representation of the portion 410 identified in FIG. 18A. FIG. 18B shows the point 420 about where the maximum impact generation rate is experienced in the device. FIG. 19A is a graphical representation of a TCAD simulation showing the impact generation rate at breakdown for an exemplary LDMOS device of the invention. FIG. 19B is a more detailed representation of the portion 430 identified in FIG. 19A. FIG. 19B shows the point 440 about where the maximum impact generation rate is experienced in the device. FIGS. 18A-19B illustrate that the impact generation rate at breakdown is not materially affected by the discrete p-top structure for the LDMOS device of the invention relative to the impact generation rate at breakdown for a conventional LDMOS device. Thus, the LDMOS device of the invention demonstrates a similar depression capability to that of a conventional device and the maximum breakdown voltage is not materially affected.

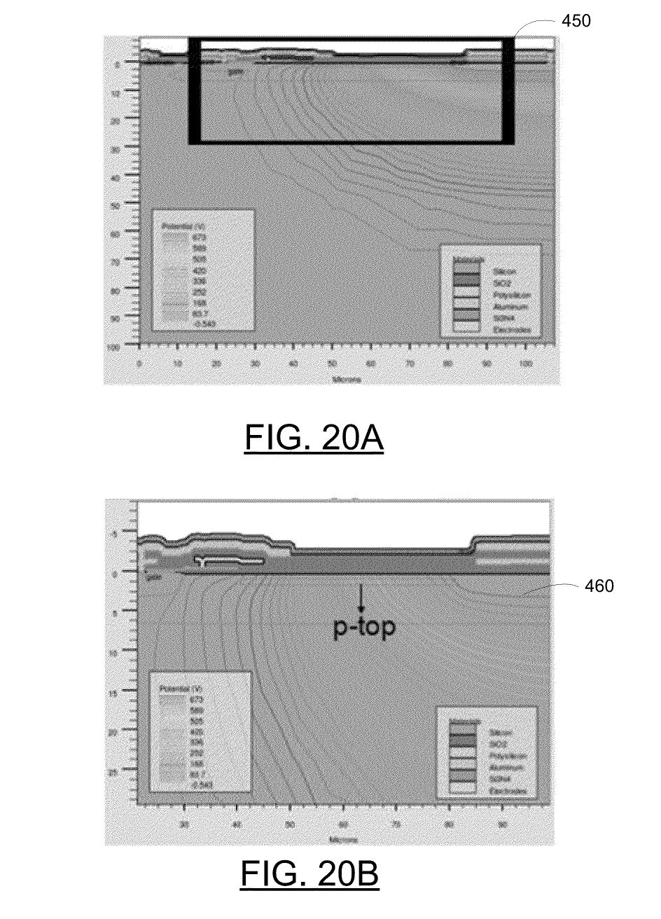

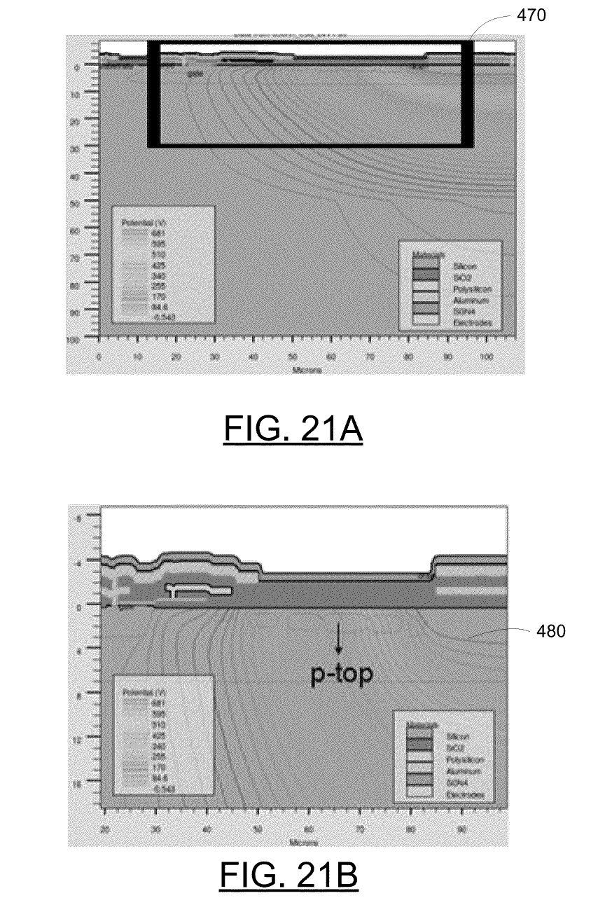

FIG. 20A is a graphical representation of a TCAD simulation showing the potential at breakdown for a conventional LDMOS device. FIG. 20B is a more detailed representation of the portion 450 identified in FIG. 18A. FIG. 20B shows the line 460 of greatest potential experienced in the device. FIG. 21A is a graphical representation of a TCAD simulation showing the potential at breakdown for an exemplary LDMOS device of the invention. FIG. 21B is a more detailed representation of the portion 470 identified in FIG. 21A. FIG. 21B shows the line 480 of greatest potential experienced in the device. FIGS. 20A-21B illustrate that the distribution of potential at breakdown is not materially affected between a conventional LDMOS device and an LDMOS device of the invention. Thus, the LDMOS device of the invention demonstrates a potential profile at breakdown that is similar to that of a conventional device and the maximum breakdown voltage is not materially affected.

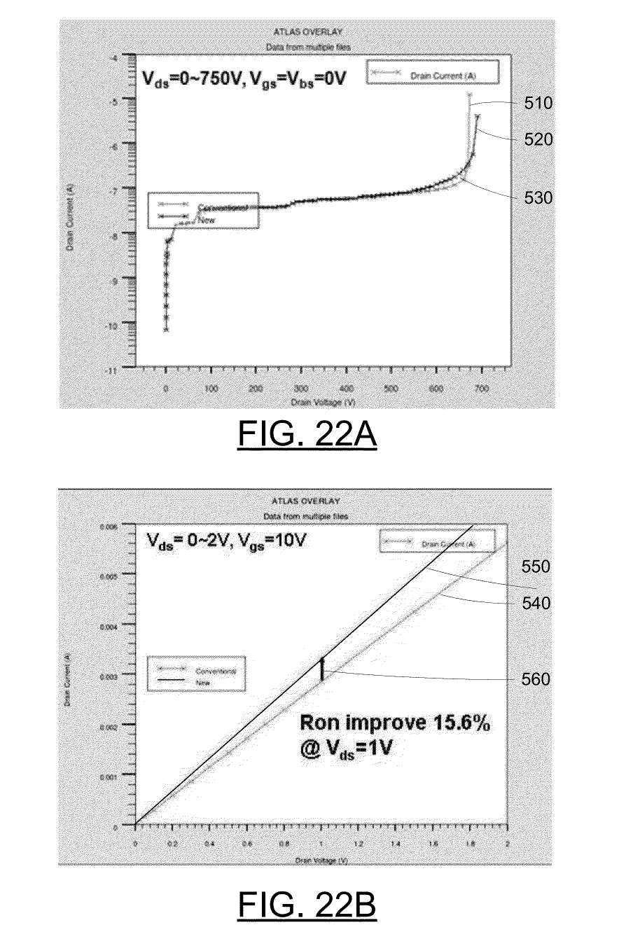

FIG. 22A is a graphical representation of the drain voltage versus the drain current for a conventional LDMOS device 510 and an exemplary LDMOS device 520 of the invention. FIG. 22A illustrates that the maximum breakdown voltage 530 is about the same between the conventional LDMOS device and the LDMOS device of the invention.

FIG. 22B is another graphical representation of the drain voltage versus the drain current for a conventional LDMOS device 540 and an exemplary LDMOS device 550 of the invention. FIG. 22B illustrates the exemplary LDMOS device of the invention provides a 15.6% improvement in the on-resistance 560 at a drain voltage of 1 volt over the on-resistance of the conventional LDMOS device having a continuous p-top region.

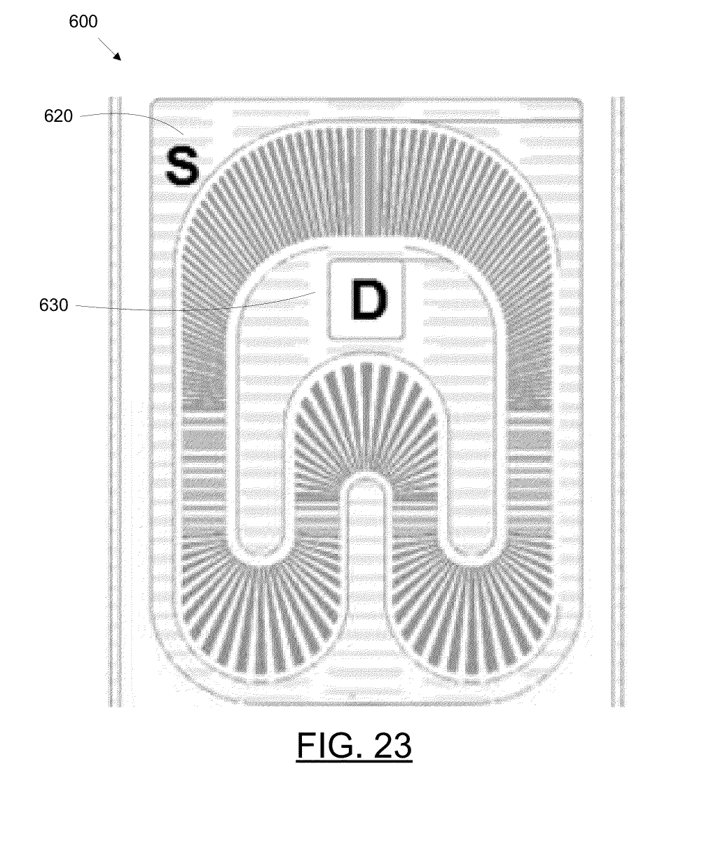

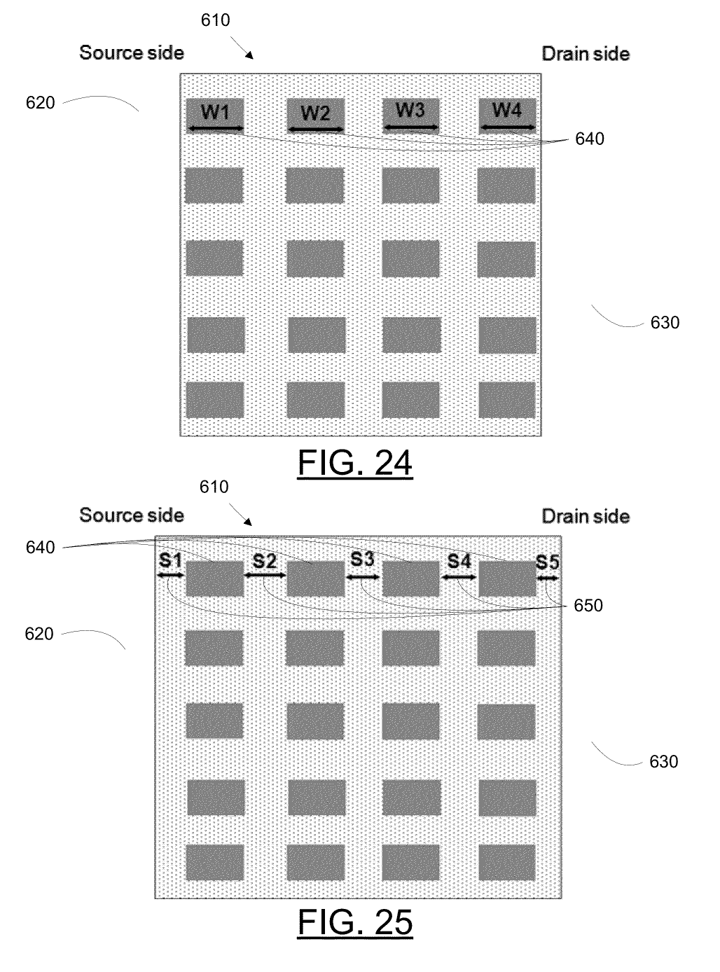

FIG. 23 is a plan view of an exemplary LDMOS device 600 according to an embodiment of the invention having a source side 620 and a drain side 630. FIG. 24 illustrates a detail view of a portion of the exemplary LDMOS device 600 of FIG. 23 showing four discrete p-top segments 640 have widths W₁, W₂, W₃, and W₄. As already provided herein, the discrete p-top region may have any number of p-top segments, but for illustrative purposes FIG. 24 represents an embodiment having four. In an embodiment of the invention, the widths W₁, W₂, W₃, and W₄ of the p-top segments 640 may be substantially about the same. In certain other embodiments, the widths W₁, W₂, W₃, and W₄ of the p-top segments 640 may be varied to achieve a desired reduction in on-resistance without substantially affecting the maximum breakdown voltage. In certain embodiments of the invention, implantation concentration for the p-top segments 640 and spacing of the p-top segments 640 may be varied to achieve a fully depleted condition even though widths of the p-top segments 640 are different. In certain embodiments of the invention, simultaneously adjustments in implantation concentration and spacing of the p-top segments 640 allow for an improved on-resistance while still substantially maintaining a high breakdown voltage at the same time.

FIG. 25 illustrates a detail view of a portion of the exemplary LDMOS device 600 of FIG. 23 showing four discrete p-top segments 640 having spacing distances S₁, S₂, S₃, S₄, and S₅ 650. As already provided herein, the discrete p-top region may have any number of p-top segments, but for illustrative purposes FIG. 25 represents an embodiment having four. In an embodiment of the invention, the distances S₁, S₂, S₃, S₄, and S₅ 650 between the p-top segments 640 may be substantially about the same. In certain other embodiments of the invention, the distances S₁, S₂, S₃, S₄, and S₅ 650 between the p-top segments 640 may be varied to achieve a desired reduction in on-resistance without substantially affecting the maximum breakdown voltage. In certain embodiments of the invention, implantation concentration for the p-top segments 640 and widths of the p-top segments 640 may be varied to achieve a fully depleted condition even though spacing of the p-top segments 640 are different. In certain embodiments of the invention, simultaneously adjustments in implantation concentration and widths of the p-top segments 640 allow for an improved on-resistance while still substantially maintaining a high breakdown voltage at the same time.

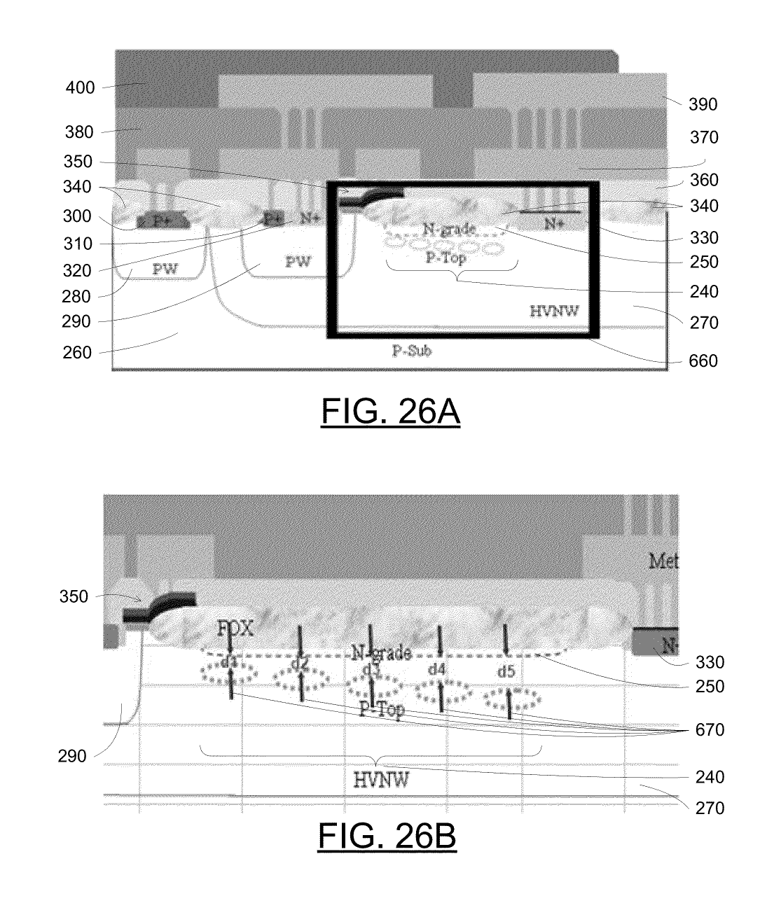

FIG. 26A illustrates a cross-sectional view of the LDMOS device according to an embodiment of the invention as fully illustration in FIG. 5A. FIG. 26B illustrates a more detailed cross-sectional view of the section 660 of the LDMOS device illustrated in FIG. 26A according to an embodiment of the invention. The discrete top region 240 having five p-top segments 670 having respective distances d₁, d₂, d₃, d₄, and d₅ from the n-grade region 250. As already provided herein, the discrete p-top region 240 may have any number of p-top segments, but for illustrative purposes FIGS. 26A & 26B represents an embodiment having five. According to an embodiment of the invention, the distances d₁, d₂, d₃, d₄, and d₅ of the p-top segments 670 from the n-grade region 250 may be substantially about the same. In certain other embodiments of the invention, the distances d₁, d₂, d₃, d₄, and d₅ of the p-top segments 670 from the n-grade region 250 may be different. For example, in an embodiment of the invention the distances d₁, d₂, d₃, d₄, and d₅ of the p-top segments 670 from the n-grade region 250 may be increasing to cause the p-top segments 670 to progressively penetrate deeper into the HVNW 270.

Indeed any of the variables generally represented as Wᵢ, Sᵢ, and dᵢ of a p-top segment for any, any combination of, or even all of the p-top segments of the discrete p-top region may be configured to provide at least about 5% improvement, at least about 10% improvement, at least about 15% improvement, at least about 20% improvement, or at least about 25% improvement in the on-resistance compared to a conventional LDMOS device having a substantially continuously disposed p-top region.

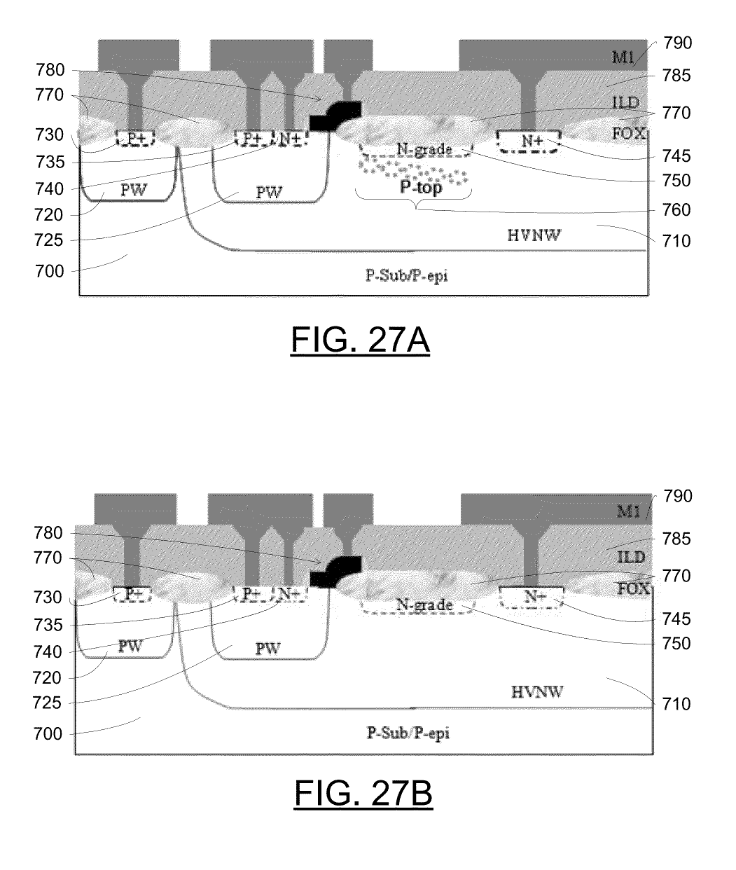

FIG. 27A illustrates a cross-sectional view of an N-channel metal oxide semiconductor (NMOS) device, in particular, an ultra-high voltage NMOS device, having a discrete p-top region according to an embodiment of the invention. The exemplary embodiment illustrated in FIG. 27A showing a p-substrate 700, which may be formed in whole or in part as a p-type epitaxial layer, in which an HVNW 710 has been disposed. A first p-well 720 is formed in the p-substrate 700 while a second p-well 725 is formed in the HVNW 710, the first p-well 720 having a first p+ doped region 730 and the second p-well 725 having a second p+ doped region 735 adjacent to an n+ doped source region 740. An n+ doped drain region 745 is formed in the HVNW 710. This section of the NMOS device is represented by an n-grade region 750 disposed above a discrete p-top region 760 having a plurality of p-top segments. A field oxide isolation region 770 substantially separates the doped regions 730, 735 & 740, 745. The NMOS also having a control gate structure 780, an interlayer dielectric layer 785 and a conductive layer 790.

FIG. 27B illustrates a cross-sectional view of an n-grade section of the NMOS device without the discrete p-top region.

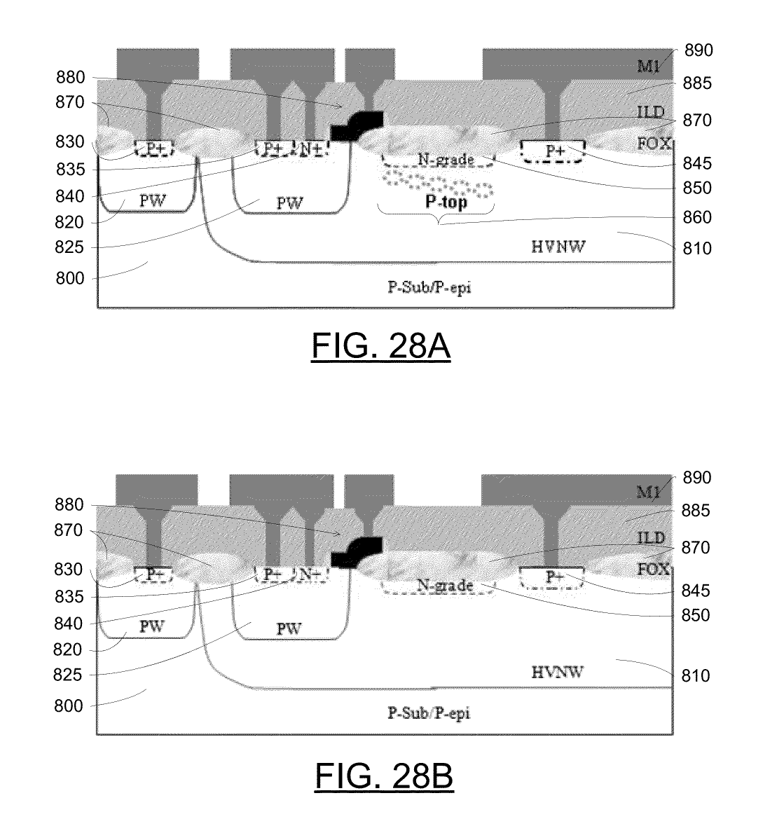

FIG. 28A illustrates a cross-sectional view of an insulated gate bipolar transistor (IGBT) device, in particular, an ultra-high voltage IGBT device, having a discrete p-top region according to an embodiment of the invention. The exemplary embodiment illustrated in FIG. 28A showing a p-substrate 800, which may be formed in whole or in part as a p-type epitaxial layer, in which an HVNW 810 has been disposed. A first p-well 820 is formed in the p-substrate 800 while a second p-well 825 is formed in the HVNW 810, the first p-well 820 having a first p+ doped region 830 and the second p-well 825 having a second p+ doped region 835 adjacent to an n+ doped region 840. A third p+ doped region 845 is formed in the HVNW 810. This section of the NMOS is represented by an n-grade region 850 disposed above a discrete p-top region 860 having a plurality of p-top segments. A field oxide isolation region 870 substantially separates the doped regions 830, 835, 840, 845. The IGBT device also having a control gate structure 880, an interlayer dielectric layer 885, and a conductive layer 890.

FIG. 28B illustrates a cross-sectional view of an n-grade section of the IGBT device without the discrete p-top region.

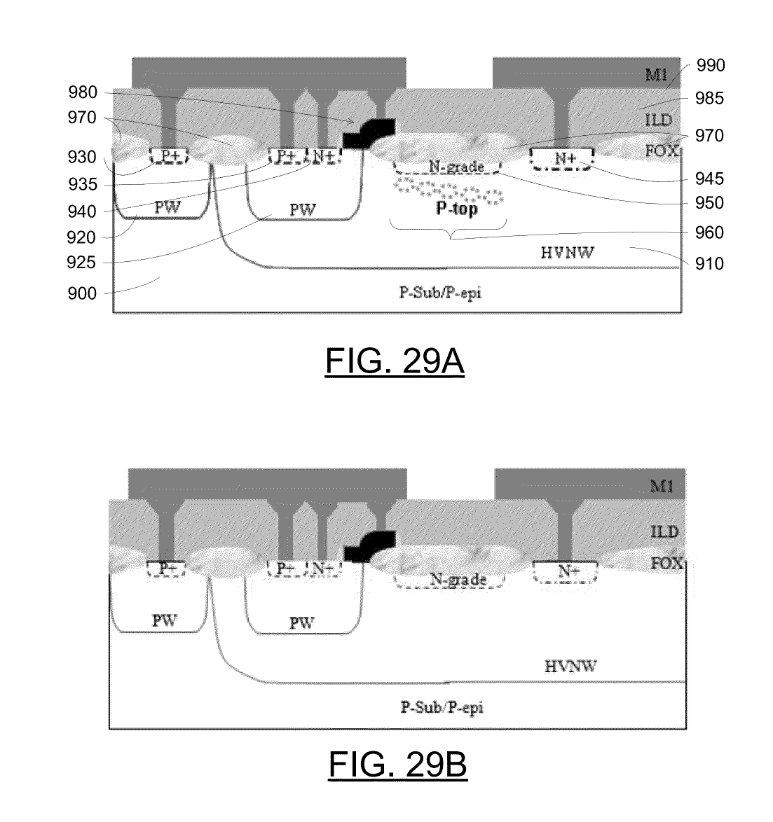

FIG. 29A illustrates a cross-sectional view of a diode, in particular, an ultra-high voltage diode, having a discrete p-top region according to an embodiment of the invention. The exemplary embodiment illustrated in FIG. 29A showing a p-substrate 900, which may be formed in whole or in part as a p-type epitaxial layer, in which an HVNW 910 has been disposed. A first p-well 920 is formed in the p-substrate 900 while a second p-well 925 is formed in the HVNW 910, the first p-well 920 having a first p+ doped region 930 and the second p-well 925 having a second p+ doped region 935 adjacent to an n+ doped source region 940. An n+ doped drain region 945 is formed in the HVNW 910. This section of the NMOS is represented by an n-grade region 950 disposed above a discrete p-top region 960 having a plurality of p-top segments. A field oxide isolation region 970 substantially separates the doped regions 930, 935, 940, 945. The IGBT device also having a control gate structure 980, an interlayer dielectric layer 985, and a conductive layer 990.

FIG. 29B illustrates a cross-sectional view of an n-grade section of the diode without the discrete p-top region.

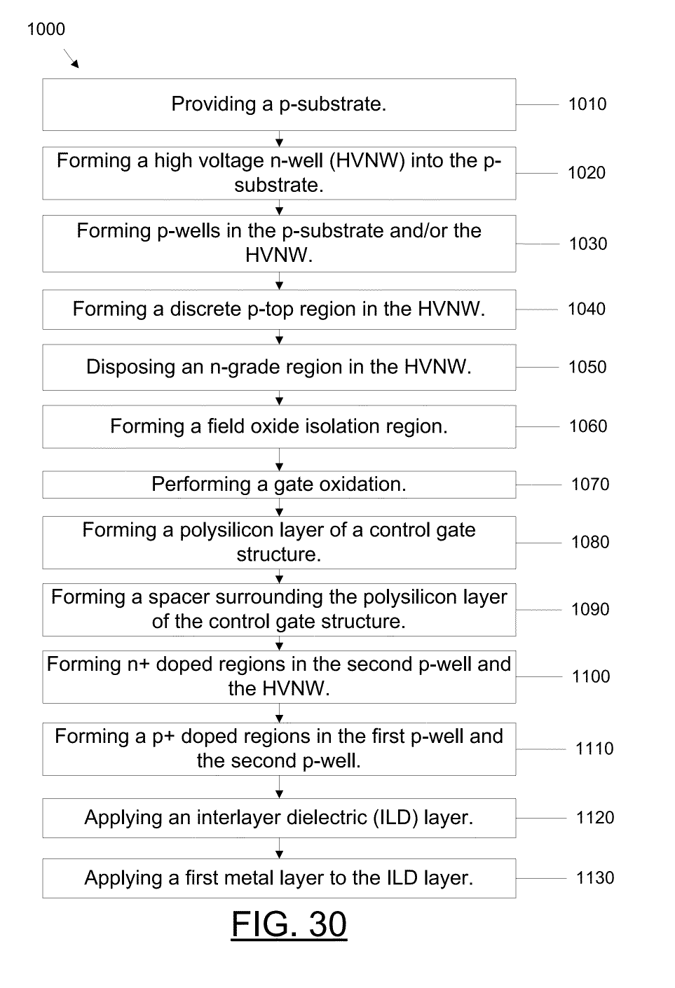

FIG. 30 is a flowchart illustrating a process for fabricating a LDMOS device according to an embodiment of the invention. The process for fabricating a LDMOS device 1000 comprises the steps of providing a p-substrate 1010, forming a high voltage n-well into the p-substrate 1020, forming p-wells in the p-substrate and the HVNW 1030, forming discrete p-top regions in the HVNW 1040, disposing an n-grade region in the HVNW 1050, forming a field oxide isolation region 1060, and forming control gate structure. The step of forming a control gate structure may comprise the steps of performing a gate oxidation 1070, forming a polysilicon layer of the control gate structure 1080, and forming a spacer surrounding the polysilicon layer of the control gate structure 1090.

The process for fabricating a LDMOS device 1000 may additionally comprise the steps of forming n+ doped regions in the second p-well and the HVNW 1100, forming p+ doped regions in the first p-well and the second p-well 1110, applying an interlayer dielectric layer 1120, and applying a first metal layer to the interlayer dielectric layer 1130. The process for fabricating a LDMOS device 1000 may comprise additional steps, for example, such as forming an IMD layer and/or a second metal layer.

An aspect of the invention provides a LDMOS device fabricated according to a method of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A MOS device comprising:
a p-substrate;
a high voltage n-well (HVNW) disposed in the p-substrate;
a first p-well formed in the p-substrate having a first p+ doped region;
a second p-well formed in the HVNW having a second p+ doped region adjacent to an n+ doped source region;
a discrete p-top region having a plurality of p-top segments disposed in the HVNW; and
an n-grade region disposed above the discrete p-top region,
wherein each of the plurality of p-top segments having a distance from the n-grade region to define a plurality of distances, a width to define a plurality of widths and a separation distance with an adjacent p-top segment to define a plurality of separation distances.

2. The MOS device of claim 1, wherein the MOS device is a LDMOS device and the HVNW having an n+ doped drain region.

3. The MOS device of claim 2, wherein each of the distances of the plurality of distances is the same.

4. The MOS device of claim 2, wherein the distances of the plurality of distances are increasing.

5. The MOS device of claim 2, wherein a number of the plurality p-top segments, the plurality of distances, the plurality of widths, and the plurality of separation distances are such that there is at least about a 15% reduction in on-resistance at a drain voltage of about 1 volt in comparison to another LDMOS device having by a continuous p-top region.

6. The MOS device of claim 5, wherein a breakdown voltage of the LDMOS device is about the same as a breakdown voltage of the another LDMOS device.

7. The MOS device of claim 2, additionally comprising a field oxide isolation region disposed to isolate the first p+ doped region, the second p+ doped region adjacent to the n+ doped source region, and the n+ doped drain region.

8. The MOS device of claim 7, additionally comprising a gate structure disposed between the n+ doped source region and the n+ doped drain region.

9. The MOS device of claim 1, wherein the MOS device is an insulated gate bipolar transistor and the HVNW having a third p+ doped region.

10. The MOS device of claim 1, wherein the MOS device is a diode and the HVNW having an n+ doped drain region.

11. A method for fabricating a MOS device comprising:
providing a p-substrate layer;
forming a high voltage n-well (HVNW) into the p-substrate;
forming a first p-well in the p-substrate;
forming a second p-well in the HVNW;
forming a discrete p-top region in the HVNW, the discrete p-top region having a plurality of p-top segments; and
disposing an n-grade region in the HVNW above the discrete p-top region,
wherein each of the plurality of p-top segments having a distance from the n-grade region to define a plurality of distances, a width to define a plurality of widths and a separation distance with an adjacent p-top segment to define a plurality of separation distances.

12. The method of claim 11 additionally comprising forming a field oxide isolation region defined by a first field oxide structure overlapping the first p-well and the second p-well and a second field oxide structure overlapping the n-grade region.

13. The method of claim 12, additionally comprising forming a gate structure.

14. The method of claim 13, wherein forming a gate structure comprises:
performing a gate oxidation;
forming a polysilicon layer; and
forming a spacer to surround the gate structure.

15. The method of claim 13, additionally comprising
forming an n+ doped source region in the second p-well adjacent to the gate structure;
forming a first p+ doped region in the first p-well;
forming a second p+ doped region in the second p-well; and
forming a doped region adjacent to the second field oxide structure in the HVNW.

16. The method of claim 15, wherein the MOS device is a LDMOS device and the doped region is an n+ doped drain region.

17. The method of claim 16, wherein a number of the plurality p-top segments, the plurality of distances, the plurality of widths, and the plurality of separation distances are such that there is at least about a 15% reduction in on-resistance at a drain voltage of about 1 volt in comparison to another LDMOS device having a continuous p-top region.

18. The method of claim 17, wherein a breakdown voltage of the LDMOS device and a breakdown voltage of the another LDMOS device are about the same.

19. The method of claim 15, wherein the MOS device is an insulated gate bipolar transistor and the doped region is a third p+ doped region.
